(19) United States
(12) Patent Application Publication
(10) Pub. No.: US 2026/0299022 A1
(43) Pub. Date: Oct. 1, 2026

(54) METHODS, SYSTEMS, AND COMPUTER READABLE MEDIA FOR PROVIDING A TEST SYSTEM WITH EMULATION MODELING

(71) Applicant: Keysight Technologies, Inc., Santa Rosa, CA (US)

(72) Inventors: Winston Wencheng Liu, Woodland Hills, CA (US); Christian Paul Sommers, Bangor, CA (US); Peter J. Marsico, Chapel Hill, NC (US)

(21) Appl. No.: 19/691,839

(22) Filed: May 29, 2026

Related U.S. Application Data
(60) Provisional application No. 63/817,727, filed on Jun. 4, 2025.

(51) Int. Cl. G01R 31/3183

(52) U.S. Cl. CPC G01R 31/318307; G01R 31/318314

(57) ABSTRACT

A method for emulating a compute and/or communication infrastructure using a model and different sets of resources includes emulating, using a first set of resources, a compute and/or communication infrastructure and testing a device under test using the compute and/or communication infrastructure emulated using the first set of resources. Behavior of the compute and/or communication infrastructure is monitored during the testing, and a model of the compute and/or communication infrastructure is generated based on the behavior, where the model includes a construct configured to emulate the behavior using resources of lower complexity than the first set of resources. The compute and/or communication infrastructure is then emulated, using the model, with a second set of resources different from the first set of resources, and the device under test is tested using the compute and/or communication infrastructure emulated using the model and the second set of resources.

### CROSS-REFERENCE TO RELATED APPLICATIONS

This application claims the priority benefit of U.S. Provisional Patent Application Ser. No. 63/817,727, filed Jun. 4, 2025, the disclosure of which is incorporated herein by reference in its entirety.

### TECHNICAL FIELD

The subject matter described herein relates to emulating compute and/or communication infrastructure, modeling emulation behavior, and re-emulating the compute and/or communication infrastructure using different resources.

### BACKGROUND

In testing computing devices, it is often desirable to utilize a test system with the capability to emulate compute and/or communication resources. For example, it is often desirable to emulate switching fabric when testing an electronic design automation (EDA) design under test. Using an emulated switching environment is desirable because using physical resources (switches, graphics processing units (GPUs), etc.) to perform testing of a design is cost prohibitive.

Emulating physical resources using high-fidelity hardware and software can also be expensive in terms of computing power, memory, and other resources. For example, in an emulated virtual switching environment, high-fidelity emulation requires complex hardware and software resources to model the various components, their queues, and interconnections. Using such complex hardware and software resources may likewise be cost-prohibitive and non-scalable.

In light of these and other difficulties, there exists a need for improvement in emulation-based test systems.

### SUMMARY

The subject matter described herein includes an approach to testing in which compute and/or communication infrastructure emulation is performed using a first set of resources, such as a high-fidelity set of resources. The emulated compute and/or communication infrastructure is used to test a device under test, and behavior of the emulated switching or communication infrastructure is monitored and modeled. The modeled behavior of the emulated switching or communication infrastructure is used to emulate the switching or communication infrastructure on a second set of resources that is different from the first set of resources. In one example, the second set of resources is of lower fidelity than the first set of resources.

In one aspect, the subject matter described herein includes a method for emulating a compute and/or communication infrastructure using a model and different sets of resources. The method can include emulating, using a first set of resources, a compute and/or communication infrastructure, testing a device under test using the compute and/or communication infrastructure emulated using the first set of resources, monitoring behavior of the compute and/or communication infrastructure during the testing, generating, based on the behavior, a model of the compute and/or communication infrastructure, where generating the model includes modeling the behavior using a construct configured to emulate the behavior using resources of lower complexity than the first set of resources, emulating, using a second set of resources different from the first set of resources and using the model, the compute and/or communication infrastructure, and testing the device under test using the compute and/or communication infrastructure emulated using the model and the second set of resources.

In another aspect, emulating the compute and/or communication infrastructure can include emulating a switching fabric.

In another aspect, emulating the compute and/or communication infrastructure using the first set of resources can include emulating the switching fabric using emulated endpoints and emulated switch queues.

In another aspect, emulating the switching fabric can include adding emulated impairments to packets traversing the switching fabric.

In another aspect, testing the device under test can include transmitting packets to and receiving packets from the device under test.

In another aspect, generating the model can include training an artificial intelligence model to model the compute and/or communication infrastructure.

In another aspect, generating the model can include generating a statistical model of the compute and/or communication infrastructure.

In another aspect, generating the model can include generating the model to be a digital twin of the compute and/or communication infrastructure.

In another aspect, generating the model can include generating the model to emulate a different behavior from observed behavior of the compute and/or communication infrastructure.

In another aspect, the second set of resources can be lower in cost and/or complexity than the first set of resources.

A system for emulating a compute and/or communication infrastructure using a model and different sets of resources is provided. The system includes a network test system including at least one processor and is configured to emulate, using a first set of resources, a compute and/or communication infrastructure. The network test system is further configured to test a device under test using the compute and/or communication infrastructure emulated using the first set of resources. The network test system is configured to monitor behavior of the compute and/or communication infrastructure during the testing. The network test system is configured to generate, based on the behavior, a model of the compute and/or communication infrastructure, wherein generating the model includes modeling the behavior using a construct configured to emulate the behavior using resources of lower complexity than the first set of resources. The network test system is further configured to emulate, using a second set of resources different from the first set of resources and using the model, the compute and/or communication infrastructure. The network test system is further configured to test the device under test using the compute and/or communication infrastructure emulated using the model and the second set of resources.

In another aspect, the network test system can be configured to emulate the compute and/or communication infrastructure by emulating a switching fabric.

In another aspect, the network test system can be configured to emulate the switching fabric using emulated endpoints and emulated switch queues.

In another aspect, the network test system can be configured to emulate the switching fabric by adding emulated impairments to packets traversing the switching fabric.

In another aspect, the network test system can be configured to test the device under test by transmitting packets to and receiving packets from the device under test.

In another aspect, the model builder can be configured to generate the model by training an artificial intelligence model to model the compute and/or communication infrastructure.

In another aspect, the model builder can be configured to generate a statistical model of the compute and/or communication infrastructure.

In another aspect, the model builder can be configured to generate the model to be a digital twin of the compute and/or communication infrastructure.

In another aspect, the model builder can be configured to generate the model to emulate a different behavior from observed behavior of the compute and/or communication infrastructure.

In another aspect, the second set of resources can be lower in cost and/or complexity than the first set of resources.

In another aspect, the subject matter described herein includes a non-transitory computer readable medium having stored thereon computer executable instructions that when executed by at least one processor of a computer cause the computer to perform a method for emulating a compute and/or communication infrastructure using a model and different sets of resources, the method including emulating, using a first set of resources, a compute and/or communication infrastructure, testing a device under test using the compute and/or communication infrastructure emulated using the first set of resources, monitoring behavior of the compute and/or communication infrastructure during the testing, generating, based on the behavior, a model of the compute and/or communication infrastructure, where generating the model includes modeling the behavior using a construct configured to emulate the behavior using resources of lower complexity than the first set of resources, emulating, using a second set of resources different from the first set of resources and using the model, the compute and/or communication infrastructure, and testing the device under test using the compute and/or communication infrastructure emulated using the model and the second set of resources.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a readable computer medium that implements the subject matter described herein may be located on a single device or computing platform or may be distributed across multiple devices or computing platforms.

### BRIEF DESCRIPTION OF THE DRAWINGS

Exemplary implementations of the subject matter described herein will now be explained with reference to the accompanying drawings, of which:

FIG. 1 is a block diagram illustrating a network test system capable of generating data for building a model for lower cost and/or lower fidelity emulation of the same resources;

FIG. 2 is a block diagram illustrating a network test system that uses lower cost/complexity emulation resources to emulate the behavior of the system illustrated in FIG. 1;

FIG. 3A is a block diagram illustrating an event-driven model of an emulated virtual switching fabric;

FIG. 3B is a block diagram illustrating a modeled version of the emulated virtual switching fabric of FIG. 3A; and

FIG. 4 is a flow chart illustrating an exemplary process for emulating a compute and/or communication infrastructure using different sets of emulation resources.

### DETAILED DESCRIPTION

In one example, the subject matter described herein involves emulating a virtual switching fabric using high-complexity/fidelity resources, modeling the behavior of the emulated virtual switching fabric during testing of a device under test and using the model to emulate the virtual switching fabric using lower cost/lower fidelity resources.

A virtual switching fabric can be emulated using a strict behavioral model, which mimics the behavior of a real hardware or software network switch. In a strict behavioral model, queuing, congestion, forwarding, and other switching behaviors are modeled to some degree of fidelity via coded algorithms. This technique has very high fidelity but may impose real-time CPU and other resource costs to model the intricate behavior of a large-scale fabric.

The subject matter described herein utilizes learned behavior to reduce real-time processing required to emulate a compute and/or switching infrastructure. In one example, a real or simulated/emulated high-fidelity network is observed while traffic patterns are transmitted between endpoints, and data is captured concerning packet behavior. Examples of such data includes packet delay, jitter, drops, explicit congestion notification (ECN) marking, etc. The data is fed into a post-processing, reduction, or machine learning algorithm and then stored in one or more databases. The data is then used by a virtual fabric emulator to reproduce (and/or scale) network behaviors at reduced complexity and CPU cost. For example, the packet arrival time or drop probability for a given packet flow can be generated statistically using a lookup table, versus modeling thousands of switch queues that make up the entire fabric and all completing traffic flows.

One example process for implementing the subject matter described herein is as follows:
1. Build a testbed environment using high cost/high complexity test system resources (e.g., field programmable gate array (FPGA)-based hardware traffic engine/emulator and CPU/GPU-based software traffic engine/emulator).
2. Run a test case and collect data/metadata/metrics associated with the testbed resources.
3. Operate in one of the following modes:
   a. Mode 1—A user specifies a portion of the high cost/complexity testbed test resources (e.g., FPGA-based traffic generating emulations, etc.) that are to be removed and replaced with an equivalent low(er) cost/low(er) complexity emulation model (e.g., generative AI/ML model, etc.) that performs a sufficiently similar function.
   b. Mode 2—the test system is adapted to analyze test case execution(s) and identify a collection of high cost/complexity testbed resources (i.e., a portion of the testbed test resources) that are candidates for replacement by an equivalent low(er) cost/low(er) complexity emulation model (e.g., generative AI/ML model, etc.) that performs a sufficiently similar function.
4. The test system accesses the appropriate data/metadata/metrics from the test run (or collection of runs) and uses this information to construct one or more equivalent low(er) cost/low(er) complexity emulation model training datasets (e.g., generative AI/ML model training dataset).
5. The AI/ML model training dataset is used to train/build an equivalent low(er) cost/low(er) complexity emulation model (e.g., generative AI/ML model, statistical model, etc.) that mimics the collection of high(er) cost/complexity testbed resources which are to be replaced.
6. Once successfully trained, the low(er) cost/complexity emulation model (e.g., generative AI/ML model, etc.) is inserted into the testbed in place of the associated high(er) cost/complexity resources.
7. The low(er) cost/complexity emulation model-augmented/modified testbed environment is then used to execute additional tests on the associated device under test (DUT) or system under test (SUT).

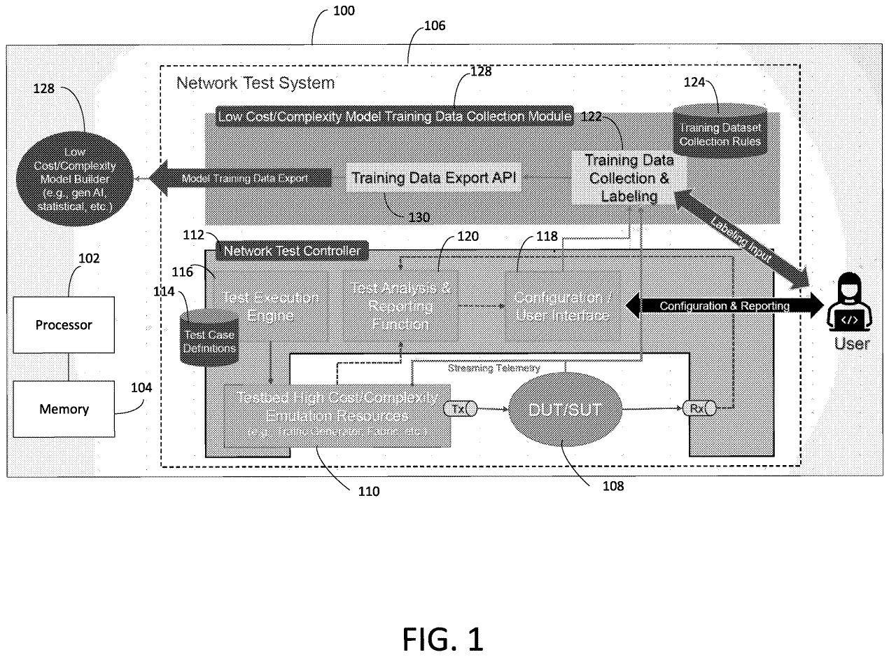

FIG. 1 is a block diagram of a computing platform that includes a network test system that emulates communication and/or compute infrastructure using a first set of resources and a model builder that generates a model of the test system emulating the first set of resources that can be executed using lower cost and/or lower complexity resources. Referring to FIG. 1, a computing platform 100 includes at least one processor 102 and memory 104. A network test system 106 executes one or more tests of a DUT/SUT 108 using high cost/high complexity emulation resources 110. In one example, network test system 106 emulates the physical switches of a data center switching fabric and DUT/SUT 108 is a device connected to the emulated switching fabric. In one example, DUT/SUT 108 may be a processor, a switch, an electronic design automation (EDA) emulator connected to an electronic design under test, etc.

A network test controller 112 controls the execution of test cases 114 by a test execution engine 116. A user supplies configuration information for each test via a configuration user interface 118. A test analysis and reporting function 120 analyzes and reports test results. In one example, training data from a test is collected by a training data collection and labeling module 122 according to training dataset collection rules 124. The training data may include network traffic, performance, and other operational data from the test case execution. The user may provide labeling input for the training data. A model training data collection module 126 may collect the training data collected during the initial test and provide it to a model builder 128 via a training data export application programming interface (API) 130.

Model builder 128 may generate a model of execution of the test case that will achieve the same or similar results of testing DUT/SUT 108, but the model may execute on resources of lower cost and/or complexity than emulation resources 110. In addition to generating a model that implements the observed behavior during the initial test, the model generated by model builder 128 may also be capable of emulating operations that were not observed during the initial test. Given the information recorded during the initial test, model builder 128 may interpolate or extrapolate, from the data, information for emulating non-observed scenarios. For example, if, during the first test execution, oversubscription of emulated switching resources is observed at 1:1 oversubscription, 1:4 oversubscription, and 1:8 oversubscription, the model may emulate 1:5, 1:10 or other user specified over-subscription of emulated switching resources.

In one example the initial test execution may produce packets that are impaired with certain impairments, such as packet delays, jitter, and loss. The initial emulation may be achieved by modeling real network switches, including switch queues, to produce the impairments. Model builder 128 may generate a model of the observed impairments that can be executed on lower cost hardware and software without emulating the real switches. For example, the model may be implemented using a lookup table or a high-speed generative AI model that implements the observed impairments.

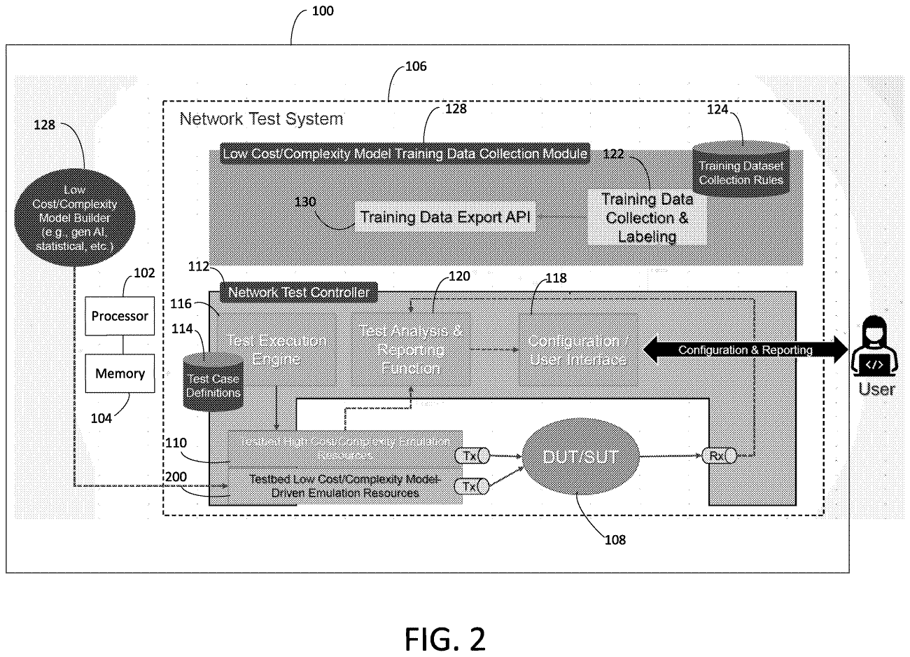

FIG. 2 is a block diagram of a computing platform that includes a different set of resources than the computing platform in FIG. 1 and executes the model created using the data illustrated in FIG. 1. In the example illustrated in FIG. 2, a portion of the high cost/complexity test resources are effectively replaced by the relatively low cost/complexity generative AI/ML emulation model described above. The same or new test cases can then be executed in the new “hybrid” testbed environment. Continuing with the switching fabric emulation example, the model output by model builder 128 may be a lookup table, statistical model, AI model, or combination thereof that implements packet impairments that would be experienced by packets traversing a switching fabric. Rather than emulating the actual switches using high complexity resources 110, the model implements the same impairments using lower cost resources 200. The model executing on lower cost resource 200 is used to test DUT/SUT 108, test results are recorded, and model complexity can be iteratively reduced.

It will be appreciated that in some contemplated use case scenarios, the low cost/low complexity model which is constructed may be used not only to replace a portion of the high cost/high complexity test resources in the test system testbed, but also to effectively scale up the size of the testbed. That is to say, a low cost/low complexity model generated by the test system may be used to add to/scale up the size of an emulated network environment associated with a test case. For example, using low cost/low complexity model building techniques described above, a low cost/low complexity model of a small collection of network components (e.g., 10 components, such as fabric switches, routers, application servers, firewalls, IoT devices, endpoint devices, network virtualization function elements, etc.) is generated during the testing of a DUT/SUT. This low cost/low complexity model is then used to scale the 10-component emulation to an associated 1000-component emulation, and the scaled 1000-component emulation is subsequently used by the test system to perform a larger-scale test on the DUT/SUT.

It will also be appreciated that a given high cost/high complexity testbed environment may be effectively broken down into and replaced by a collection of multiple low cost/low complexity emulation models that operate in a coordinated manner to execute a test on a DUT/SUT.

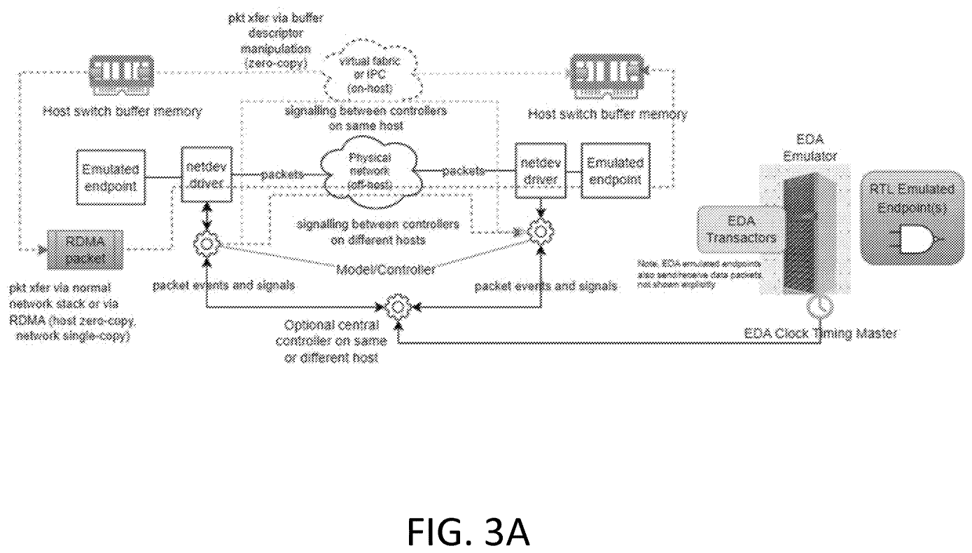

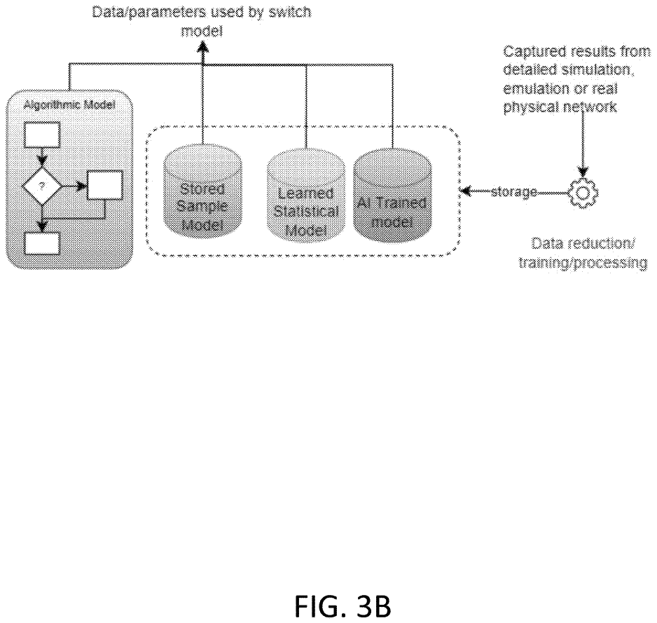

FIG. 3A illustrates an example of a virtual switching fabric emulated using a first set of resources, and FIG. 3B illustrates an example of a modeled emulation of the virtual switching fabric in FIG. 3A using a second set of resources that is less complex and/or less costly than the first set of resources. The virtual switching fabric illustrated in FIG. 3A is modeled using network device interfaces (netdevs) connected via buffer memories, all controlled by a discrete event behavioral model modeling receiving events from the endpoints and an EDA timing master and sending signals to the various components to control the transfer of packets. Packet data is moved via buffer descriptor management (for intra-host packet transfer) or across a physical network (for inter-host transfer). A perfect model will reproduce the same behavior as a network of real switches.

Signals and events can be communicated between elements on the same host using short network packets, interprocessor communications (IPC), or other techniques. Signals and events between controllers on different hosts can use short, packetized messages. The final outcome is the transfer of packets (if not dropped) between buffer memories in the endpoints' bound netdevs. The design can begin as a pure discrete simulation modeling the generation and flow of packets through a fabric. The model can be used as an emulation controller to interact with network device drivers, buffer descriptors, and remote direct memory access (RDMA) stacks to move data generated by endpoints.

The modeled or emulated virtual switching fabric in FIG. 3A can be thought of as the strict behavioral model discussed above in which real switches, endpoints, and interconnections are emulated. In contrast, the behavioral model illustrated in FIG. 3B uses stored data samples collected from the behavioral model illustrated in FIG. 3A to parameterize a statistical model or train an AI model to mimic the behavior of the model illustrated in FIG. 3A. The model illustrated in FIG. 3B does not expressly emulate all of the components illustrated in FIG. 3A but instead uses a statistical model or a trained machine learning model to mimic the behavior of the model illustrated in FIG. 3A. For example, if the observed model behavior in FIG. 3A is a delay in packets modeled by congestion in switching queues, the model illustrated in FIG. 3B may utilize a probability distribution or a trained neural network to produce the same packet delay distribution observed for the model illustrated in FIG. 3A.

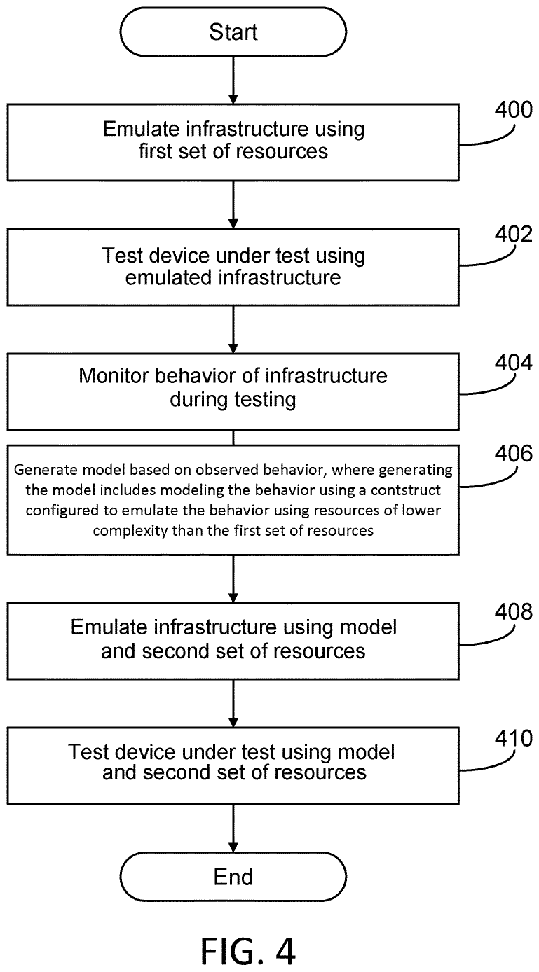

FIG. 4 is a flow chart illustrating an exemplary process for emulating a compute and/or communication infrastructure using a model and different sets of resources. Referring to FIG. 4, in step 400, the process includes emulating, using a first set of resources, a compute and/or communication infrastructure. For example, the first set of resources may include high cost/high complexity emulation resources 110, such as an FPGA-based traffic engine/emulator and CPU/GPU-based software that emulate endpoints, switch queues, and links of a virtual switching fabric for testing DUT/SUT 108.

In step 402, the process further includes testing a device under test using the compute and/or communication infrastructure emulated using the first set of resources. For example, the network test system 106 may execute one or more test cases 114 in which packets are transmitted to and received from DUT/SUT 108 through the emulated switching fabric to evaluate forwarding behavior, congestion handling, oversubscription behavior, or other network-related performance characteristics.

In step 404, the process further includes monitoring behavior of the compute and/or communication infrastructure during the testing. For example, the test system may monitor packet delay, jitter, packet drops, ECN marking, queue occupancy, and traffic-flow timing information produced while the emulated endpoints and switching resources process traffic associated with the test case.

In step 406, the process further includes generating, based on the behavior, a model of the compute and/or communication infrastructure, where generating the model includes modeling the behavior using a construct configured to emulate the behavior using resources of lower complexity than the first set of resources. For example, model builder 128 may use the monitored data to generate a construct, such as a lookup table, a statistical model, or a trained artificial intelligence/machine learning (AI/ML) model (e.g., a convolutional neural network model, a recurrent neural network model, a transformer neural network model, etc.), that is designed to reproduce, using lower complexity resources, observed packet impairments, such as latency, jitter, and loss distributions, for traffic traversing the emulated switching fabric. The modeling is achieved by emulating the impairments that would be experienced by traffic traversing the emulated switching fabric but without directly emulating the individual components (switches, queues, network interfaces, etc.) of the emulated switching fabric. Instead of directly emulating the emulated switching fabric components, the model emulates observed packet behaviors using a construct, such as a lookup table, a statistical model, or a machine learning model, designed to run on lower complexity resources than the initial emulation.

In step 408, the process further includes emulating, using a second set of resources different from the first set of resources and using the model, the compute and/or communication infrastructure. For example, lower cost resources 200 may execute the generated lookup table, statistical model, or AI/ML model to emulate the packet impairments and traffic behavior of the original virtual switching fabric without explicitly emulating each switch, queue, and interconnection in the first set of resources.

In step 410, the process further includes testing the device under test using the compute and/or communication infrastructure emulated using the model and the second set of resources.

As indicated above, the analysis described herein used to generate the emulation models is not limited to AI/ML analysis or training. In another example, the analysis could be statistical, and the execution may be probabilistic. In addition, the subject matter described herein includes more than a simple statistical analysis by sampling into the observed distribution. In addition, the observed data can be used to train a fabric behavior predictor by training an AI/ML model to predict the queuing/loss/latency delays.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A method for emulating a compute and/or communication infrastructure using a model and different sets of resources, the method comprising:
emulating, using a first set of resources, a compute and/or communication infrastructure;
testing a device under test using the compute and/or communication infrastructure emulated using the first set of resources;
monitoring behavior of the compute and/or communication infrastructure during the testing;
generating, based on the behavior, a model of the compute and/or communication infrastructure, wherein generating the model includes modeling the behavior using a construct configured to emulate the behavior using resources of lower complexity than the first set of resources;
emulating, using a second set of resources different from the first set of resources and using the model, the compute and/or communication infrastructure; and
testing the device under test using the compute and/or communication infrastructure emulated using the model and the second set of resources.

2. The method of claim 1 wherein emulating the compute and/or communication infrastructure includes emulating a switching fabric.

3. The method of claim 2 wherein emulating the compute and/or communication infrastructure using the first set of resources includes emulating the switching fabric using emulated endpoints and emulated switch queues.

4. The method of claim 2 wherein emulating the switching fabric includes adding emulated impairments to packets traversing the switching fabric.

5. The method of claim 1 wherein testing the device under test includes transmitting packets to and receiving packets from the device under test.

6. The method of claim 1 wherein generating the model includes training an artificial intelligence model to model the compute and/or communication infrastructure.

7. The method of claim 1 wherein generating the model includes generating a statistical model of the compute and/or communication infrastructure.

8. The method of claim 1 wherein generating the model includes generating the model to be a digital twin of the compute and/or communication infrastructure.

9. The method of claim 1 wherein generating the model includes generating the model to emulate a different behavior from observed behavior of the compute and/or communication infrastructure.

10. The method of claim 1 wherein the second set of resources is lower in cost and/or complexity than the first set of resources.

11. A system for emulating a compute and/or communication infrastructure using a model and different sets of resources, the system comprising:
a network test system including at least one processor and configured to emulate, using a first set of resources, a compute and/or communication infrastructure;
the network test system further configured to test a device under test using the compute and/or communication infrastructure emulated using the first set of resources;
the network test system further configured to monitor behavior of the compute and/or communication infrastructure during the testing;
a model builder configured to generate, based on the behavior, a model of the compute and/or communication infrastructure, wherein generating the model includes modeling the behavior using a construct configured to emulate the behavior using resources of lower complexity than the first set of resources;
the network test system further configured to emulate, using a second set of resources different from the first set of resources and using the model, the compute and/or communication infrastructure; and
the network test system further configured to test the device under test using the compute and/or communication infrastructure emulated using the model and the second set of resources.

12. The system of claim 11 wherein the network test system is configured to emulate a switching fabric.

13. The system of claim 12 wherein the network test system is configured to emulate the switching fabric using emulated endpoints and emulated switch queues.

14. The system of claim 12 wherein the network test system is configured to emulate the switching fabric by adding emulated impairments to packets traversing the switching fabric.

15. The system of claim 11 wherein the network test system is configured to test the device under test by transmitting packets to and receiving packets from the device under test.

16. The system of claim 11 wherein the model builder is configured to generate the model by training an artificial intelligence model to model the compute and/or communication infrastructure.

17. The system of claim 11 wherein the model builder is configured to generate a statistical model of the compute and/or communication infrastructure.

18. The system of claim 11 wherein the model builder is configured to generate the model to be a digital twin of the compute and/or communication infrastructure or to emulate a different behavior from observed behavior of the compute and/or communication infrastructure.

19. The system of claim 11 wherein the second set of resources is lower in cost and/or complexity than the first set of resources.

20. A non-transitory computer readable medium having stored thereon computer executable instructions that when executed by at least one processor of a computer cause the computer to perform a method for emulating a compute and/or communication infrastructure using a model and different sets of resources, the method comprising:
emulating, using a first set of resources, a compute and/or communication infrastructure;
testing a device under test using the compute and/or communication infrastructure emulated using the first set of resources; monitoring behavior of the compute and/or communication infrastructure during the testing;
generating, based on the behavior, a model of the compute and/or communication infrastructure, wherein generating the model includes modeling the behavior using a construct configured to emulate the behavior using resources of lower complexity than the first set of resources;
emulating, using a second set of resources different from the first set of resources and using the model, the compute and/or communication infrastructure; and
testing the device under test using the compute and/or communication infrastructure emulated using the model and the second set of resources.
